(19) United States
(12) Patent Application Publication
(10) Pub. No.: US 2026/0057939 A1
(43) Pub. Date: Feb. 26, 2026

(54) MEMORY DEVICE

(71) Applicant: SAMSUNG ELECTRONICS CO., LTD., Suwon-si (KR)

(72) Inventors: Hanmin Nam, Suwon-si (KR); Jeunghwan Park, Suwon-si (KR)

(21) Appl. No.: 19/097,541

(22) Filed: Apr. 1, 2025

(30) Foreign Application Priority Data
Aug. 20, 2024 (KR) 10-2024-0111619

(51) Int. Cl. G11C 16/04; G11C 5/06; G11C 16/14; G11C 16/26

(52) U.S. Cl. CPC G11C 16/0483; G11C 5/063; G11C 16/14; G11C 16/26

(57) ABSTRACT

Memory devices in which ground transistors of string select lines are connected to a dummy word line to reduce a chip size are provided. In one aspect, the memory device includes a memory block including cell strings respectively selected by string select lines, where each cell string is connected to word lines stacked in a vertical direction, a pass transistor circuit including pass transistors respectively connected to the plurality of string select lines and the plurality of word lines, where the pass transistors are configured to be turned on based on the memory block being selected, and a ground transistor circuit including ground transistors respectively connected to word lines, where the ground transistors are configured to be turned on based on the memory block being unselected. A number of ground transistors is smaller than a number of string select lines.

### CROSS-REFERENCE TO RELATED APPLICATION

This application is based on and claims priority under 35 U.S.C. § 119 to Korean Patent Application No. 10-2024-0111619, filed on Aug. 20, 2024, in the Korean Intellectual Property Office, the disclosure of which is incorporated by reference herein in its entirety.

### BACKGROUND

Recently, along with the multifunctionalization of information and communication devices, memory devices with larger capacity and higher integration are demanded. As the size of a memory cell is reduced for high integration, operating circuits and/or wiring structures included in a memory device for operation and electrical connection of the memory device are becoming more complex. Therefore, there is a demand for a memory device having excellent electrical characteristics with improved integration. To improve the storage capacity and the integration of memory devices, non-volatile memory devices in which memory cells are stacked in a 3-dimensional structure, such as 3D NAND flash memory, have been studied.

In a 3D NAND flash memory, the number of word lines stacked in a vertical direction on a substrate may increase as the capacity of memory blocks increases. At the same time, the number of pass transistors connected to word lines may increase, thereby increasing a chip size.

### SUMMARY

The present disclosure provides memory devices capable of reducing the chip size by reducing the number of transistors in a ground transistor circuit by connecting ground transistors to dummy word lines instead of connecting the ground transistors to string select lines.

According to an aspect of the present disclosure, a memory device is provided. The memory device includes a memory block including a plurality of cell strings respectively configured to be selected by a plurality of string select lines, where each cell string of the plurality of cell strings is connected to a plurality of word lines stacked in a vertical direction; a pass transistor circuit including a plurality of pass transistors respectively connected to the plurality of string select lines and the plurality of word lines, where the plurality of pass transistors are configured to be turned on based on the memory block being selected; and a ground transistor circuit including a plurality of ground transistors respectively connected to the plurality of word lines, where the plurality of ground transistors are configured to be turned on based on the memory block being unselected, where a number of the ground transistors is smaller than a number of the plurality of string select lines.

According to another aspect of the present disclosure, a memory device is provided. The memory device includes a memory block formed on a first semiconductor layer and including a plurality of cell strings respectively selected by a plurality of string select lines, where each cell string comprises a plurality of memory cells respectively connected to a plurality of word lines stacked in a vertical direction; a plurality of dummy word lines formed on the first semiconductor layer and positioned between the plurality of string select lines and a ground select line; a pass transistor circuit formed on a second semiconductor layer positioned below the first semiconductor layer in the vertical direction, the pass transistor circuit including a plurality of pass transistors respectively connected to the plurality of string select lines, the plurality of word lines, the plurality of dummy word lines and the ground select line, where the plurality of pass transistors are configured to be turned on based on the memory block being selected; and a ground transistor circuit formed on the second semiconductor layer, the ground transistor circuit including at least one ground transistor connected to at least one of the plurality of dummy word lines, where the at least one ground transistor is configured to be turned on based on the memory block being unselected.

According to another aspect of the present disclosure, a memory device is provided. The memory device includes a memory block including a plurality of control lines, where the plurality of control lines comprises a plurality of string select lines, a plurality of word lines, a ground select line, and a plurality of dummy word lines arranged between the plurality of string select lines and the plurality of word lines or between the ground select line and the plurality of word lines; and the plurality of control lines comprise a first group of control lines, and the first group of control lines comprises at least one of the plurality of word lines and at least one of the plurality of dummy word lines; a pass transistor circuit including pass transistors respectively connected to the plurality of control lines; and a ground transistor circuit including at least one ground transistor respectively connected to the first group of control lines.

### BRIEF DESCRIPTION OF THE DRAWINGS

Implementations of the present disclosure will be more clearly understood from the following detailed description taken in conjunction with the accompanying diagrams in which:

FIG. 1 is a block diagram showing an example memory device;

FIG. 2 is a block diagram showing an example block gating circuit and a memory cell array;

FIG. 3 is a diagram schematically showing an example structure of a memory device;

FIG. 4 is a block diagram showing an example memory cell array;

FIG. 5 is an example equivalent circuit diagram of a memory block;

FIG. 6 is a diagram illustrating an address decoder, a first ground transistor circuit, a first pass transistor circuit, and a first memory block;

FIG. 7 is a diagram illustrating an address decoder, a first ground transistor circuit, a first pass transistor circuit, and a first memory block, ;

FIG. 8 is a diagram illustrating an address decoder, a first ground transistor circuit, a first pass transistor circuit, and a first memory block, ;

FIG. 9 is a circuit diagram exemplifying a first ground transistor circuit, a first pass transistor circuit, and a first memory block;

FIG. 10 is a circuit diagram exemplifying a first ground transistor circuit, a first pass transistor circuit, and a first memory block;

FIG. 11 is a table illustrating example voltage conditions during a read operation of a memory device;

FIG. 12 is a circuit diagram showing an example operation of a first pass transistor circuit, a first ground transistor circuit, and a first memory block during a read operation of a memory device;

FIG. 13 is a table illustrating example voltage conditions during a program operation of a memory device;

FIG. 14 is a circuit diagram showing an example operation of a first pass transistor circuit, a first ground transistor circuit, and a first memory block during a program operation of a memory device;

FIG. 15 is a table illustrating example voltage conditions during an erase operation of a memory device;

FIG. 16 is a circuit diagram showing an example operation of a first pass transistor circuit, a first ground transistor circuit, and a first memory block during an erase operation of a memory device;

FIG. 17 is a block diagram showing an example in which an example memory device is applied to a solid state drive (SSD) system; and

FIG. 18 is a block diagram of a system for describing an example electronic device including a memory device.

### DETAILED DESCRIPTION

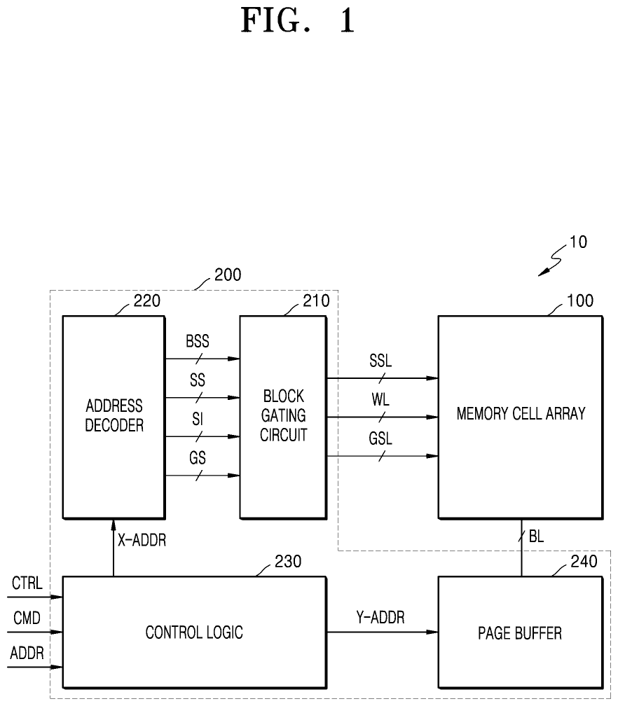

FIG. 1 is a block diagram showing a memory device 10 according to one or more implementations.

Referring to FIG. 1, the memory device 10 may include a memory cell array 100 and a peripheral circuit 200. The peripheral circuit 200 may include a block gating circuit 210, an address decoder 220, a control logic 230, and a page buffer 240. Although not shown, the peripheral circuit 200 may further include a voltage generator, a data input/output circuit, an input/output interface, a temperature sensor, or a command decoder. According to implementations, the memory device 10 may be a non-volatile memory device, and hereinafter, the “memory device” may refer to a non-volatile memory device.

The memory cell array 100 may include a plurality of memory blocks. Each memory block may include a plurality of memory cells arranged in a row-wise direction and a column-wise direction on a substrate. For example, the memory cells may be flash memory cells. Hereinafter, implementations will be described in detail based on an example case where the memory cells are NAND flash memory cells. However, the present disclosure is not limited thereto, and, in some implementations, the memory cells may be resistive memory cells like resistive RAM (ReRAM) cells, phase change RAM (PRAM) cells, and magnetic RAM (MRAM) cells. Each cell string may include a plurality of memory cells stacked in a direction perpendicular to a substrate. In other words, memory cells are provided along rows and columns on the substrate and may be stacked in a direction perpendicular to the substrate to form a 3-dimensional structure. For example, the memory cell array 100 may include a plurality of memory cells each capable of storing one or more bits. However, the present disclosure is not limited thereto. In some implementations, the memory cell array 100 may include a 2-dimensional memory cell array, and the 2-dimensional memory cell array may include a plurality of cell strings arranged in a row-wise direction and a column-wise direction.

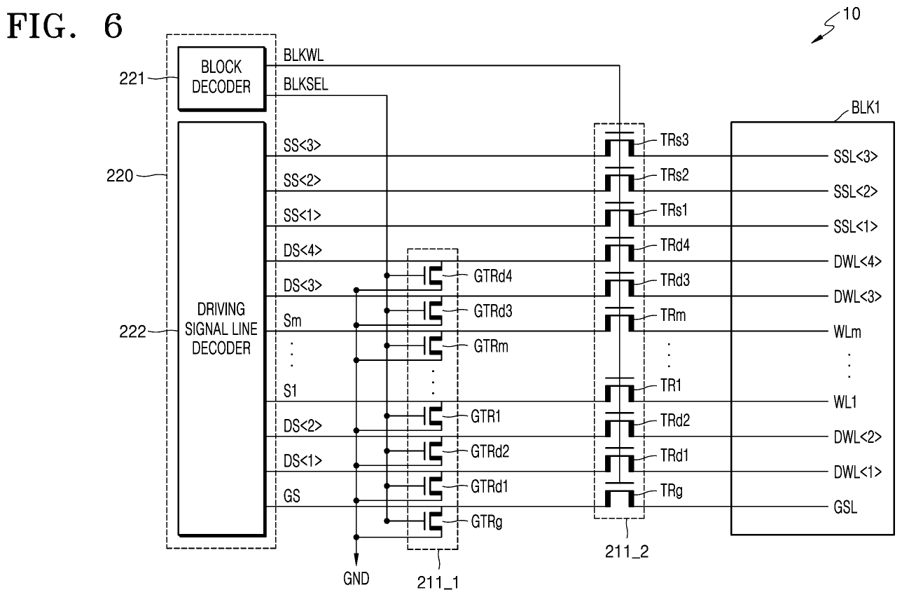

The block gating circuit 210 may be connected to the memory cell array 100 through string select lines SSL, word lines WL, and a ground select line GSL. The block gating circuit 210 may be connected to the address decoder 220 via string lines SS, select lines S, and ground lines GS. The string lines SS, the select lines S, and the ground lines GS may be referred to as “driving signal lines.” The block gating circuit 210 may receive a block select signal BSS from the address decoder 220. For example, the block select signal BSS may include a first block select signal (BLKSEL of FIG. 6) and a second block select signal (BLKWL of FIG. 6).

The block gating circuit 210 may select a memory block of the memory cell array 100 in response to the block select signal BSS. The block gating circuit 210 may electrically connect the string select lines SSL, the word lines WL, and the ground select line GSL of a selected memory block to the string lines SS, the select lines S and the ground lines GS.

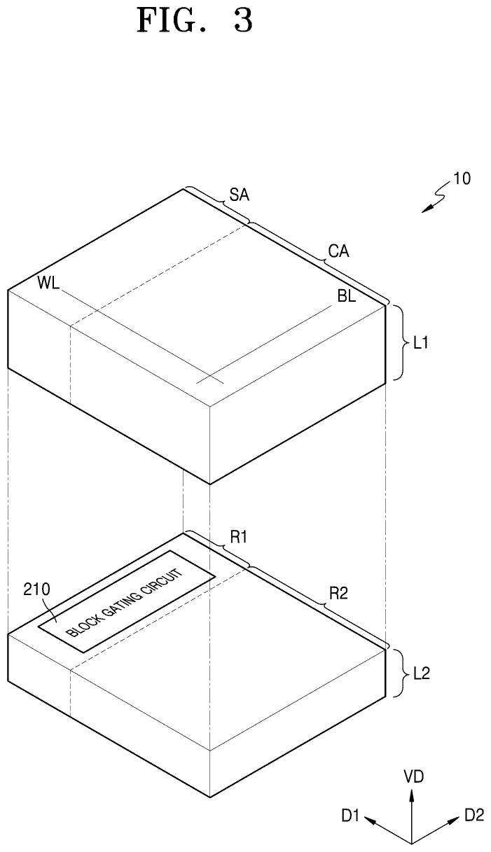

As semiconductor processes develop, as the number of memory cells arranged in the memory cell array 100 increases (in other words, as the number of the word lines WL stacked in a vertical direction increases), the number of transistors for driving the word lines WL increases, and thus the area occupied by the block gating circuit 210 increases. According to an implementation, the peripheral circuit 200 may be disposed in the vertical direction above or below the memory cell array 100, and in particular, the block gating circuit 210 may be disposed in the vertical direction above or below a stepped area of the word lines WL. Therefore, since the area in which the block gating circuit 210 is disposed overlaps the stepped area of the word lines WL in the vertical direction, an increase in the chip size of the memory device 10 may be prevented despite the increase in the number of transistors due to the increase in the number of stacked word lines WL. More detailed descriptions thereof will be given later with reference to FIG. 3.

The address decoder 220 may be connected to the block gating circuit 210 via the string lines SS, the select lines S, and the ground line(s) GS. The address decoder 220 is configured to operate in response to the control of the control logic 230. The address decoder 220 may receive a row address X-ADDR from the control logic 230.

The address decoder 220 may output the block select signal BSS for selecting one of a plurality of memory blocks in response to a received row address X-ADDR. Also, the address decoder 220 may output a word line driving signal for selecting one of the word lines WL of a selected memory block to the select lines S, output a string select line driving signal for selecting one of the string lines SS to the string select lines SSL, and output a ground select line driving signal for selecting one of ground select lines GSL to the ground lines GS, in response to the row address X-ADDR.

The page buffer 240 may be connected to the memory cell array 100 via bit lines BL. The page buffer 240 may be configured to exchange data with the outside. The page buffer 240 operates in response to the control of the control logic 230. The page buffer 240 may select some bit lines from among the bit lines BL in response to a column address Y_ADDR.

The control logic 230 may be connected to the address decoder 220 and the page buffer 240. The control logic 230 may generate various control signals for programming data into the memory cell array 100, reading data from the memory cell array 100, or erasing data stored in the memory cell array 100, based on a command CMD, an address ADDR, and a control signal CTRL. For example, the control logic 230 may output the row address X-ADDR and the column address Y-ADDR. Therefore, the control logic 230 may overall control various operations within the non-volatile memory device 10.

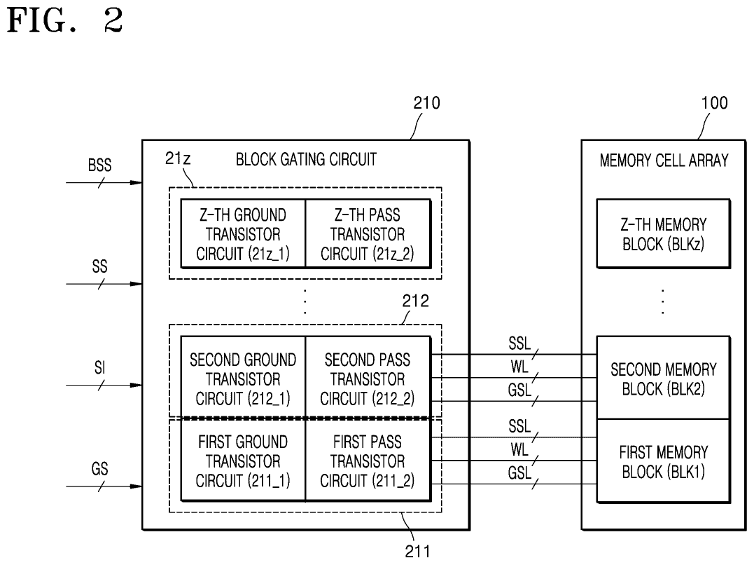

FIG. 2 is a block diagram showing the block gating circuit 210 and the memory cell array 100 according to one or more implementations.

Referring to FIG. 2, the memory cell array 100 may include a plurality of memory blocks BLK1 to BLKz. Each memory block may be connected to the block gating circuit 210 through the plurality of string select lines SSL, the plurality of word lines WL, and the ground select line GSL.

The block gating circuit 210 may include a plurality of gating circuits 211 to 21z. The plurality of gating circuits 211 to 21z may correspond to the plurality of memory blocks BLK1 to BLKz, respectively. The plurality of gating circuits 211 to 21z may include a plurality of ground transistor circuits 211_1 to 21z_1 and a plurality of pass transistor circuits 211_2 to 21z_2, respectively. Each gating circuit may include one ground transistor circuit and one pass transistor circuit.

From among the ground transistor circuits 211_1 to 21z_1, ground transistor circuits corresponding to unselected memory blocks may supply a low voltage to the ground select lines GSL of the unselected memory blocks, respectively. For example, the grounding transistor circuits 211_1 to 21z_1 may supply a ground voltage GND.

A pass transistor circuit corresponding to a selected memory block from among the pass transistor circuits 211_2 to 21z_2 may electrically connect string select lines SSL<1> to SSL<3>, first to m-th word lines WL1 to WLm, and the ground select line GSL of a selected memory block of the memory blocks BLK1 to BLKz to the string select lines SSL<1> to SSL<3>, select lines S1 to Sm, and a ground line GS, respectively, in response to the block select signal BSS.

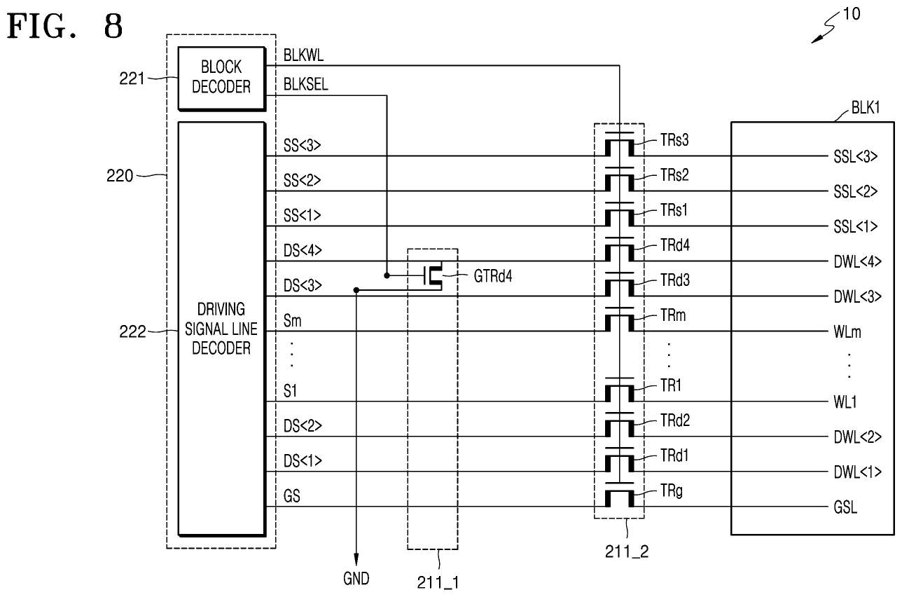

The configurations of a first ground transistor circuit 211_1 and a first pass transistor circuit 211_2 of a first block gating circuit 211 will be described in detail later with reference to FIG. 6 and FIG. 8.

FIG. 3 is a diagram schematically showing the structure of the memory device 10 according to one or more implementations.

Referring to FIGS. 1 and 3 together, the memory device 10 may include a first semiconductor layer L1 and a second semiconductor layer L2, and the first semiconductor layer L1 may be stacked in a vertical direction VD with respect to the second semiconductor layer L2. In detail, the second semiconductor layer L2 may be disposed below the first semiconductor layer L1 in the third direction D3, and thus, the second semiconductor layer L2 may be disposed close to a substrate. According to an implementation, the memory cell array 100 may be formed in the first semiconductor layer L1, and the peripheral circuit 200 may be formed in the second semiconductor layer L2. Therefore, the memory device 10 may have a structure in which the memory cell array 100 is disposed over some peripheral circuits, that is, the Cell Over Periphery (COP) structure.

The first semiconductor layer L1 may include a cell area CA and a stair area SA, and a plurality of memory cells may be arranged in the cell area CA. In the first semiconductor layer L1, the plurality of bit lines BL may extend in a second horizontal direction D2, and the plurality of word lines WL may extend in a first horizontal direction D1. One end of the plurality of word lines WL may be implemented in a stair-like shape, and, in this specification, an area including a plurality of word lines WL having a stair-like shape in the first semiconductor layer L1 is referred to as a “stair area” (SA) or a “word line extension area.”

The second semiconductor layer L2 may include a substrate, and the peripheral circuit 200 may be formed in the second semiconductor layer L2 by forming semiconductor devices such as transistors and patterns for distributing devices on the substrate. After the peripheral circuit 200 is formed on the second semiconductor layer L2, the first semiconductor layer L1 including the memory cell array 100 may be formed, and patterns for electrically connecting the word lines WL and the bit lines BL of the memory cell array 100 to the peripheral circuit 200 formed in the second semiconductor layer L2 may be formed. The second semiconductor layer L2 may include a first area R1 corresponding to the stair area SA and a second area R2 corresponding to the cell area CA. According to an implementation, the block gating circuit 210 may be disposed in the first area R1, but the present disclosure is not limited thereto.

As described above, according to the present implementations, the memory device 10 may have the COP structure, and the block gating circuit 210 may be disposed at the bottom of the stair area SA. According to an implementation, a plurality of select line driving signal lines connected to a plurality of transistor blocks included in the block gating circuit 210 may extend in the first horizontal direction D1.

The memory device 10 according to the present disclosure may be applied in a case where blocks are shared in a structure in which transistors are arranged in a plurality of stages.

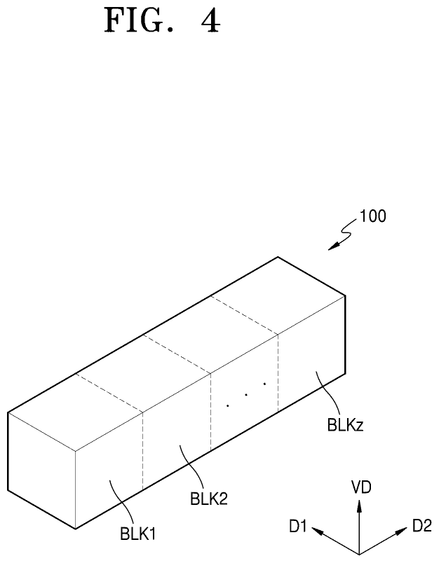

FIG. 4 is a block diagram showing the memory cell array 100 according to one or more implementations.

Referring to FIG. 4, the memory cell array 100 may include a plurality of memory blocks BLK1 to BLKz, and z may be a positive integer. The memory blocks BLK1 to BLKz may each have a 3-dimensional structure (or a vertical structure). In detail, the memory blocks BLK1 to BLKz may each include a plurality of NAND strings extending in the vertical direction VD. Here, the NAND strings may be provided to be a particular distance spaced apart from one another in the first horizontal direction D1 and the second horizontal direction D2. The memory blocks BLK1 to BLKz may be selected by an address decoder (220 of FIG. 1). For example, the address decoder 220 may select a memory block corresponding to a block address from among the memory blocks BLK1 to BLKz.

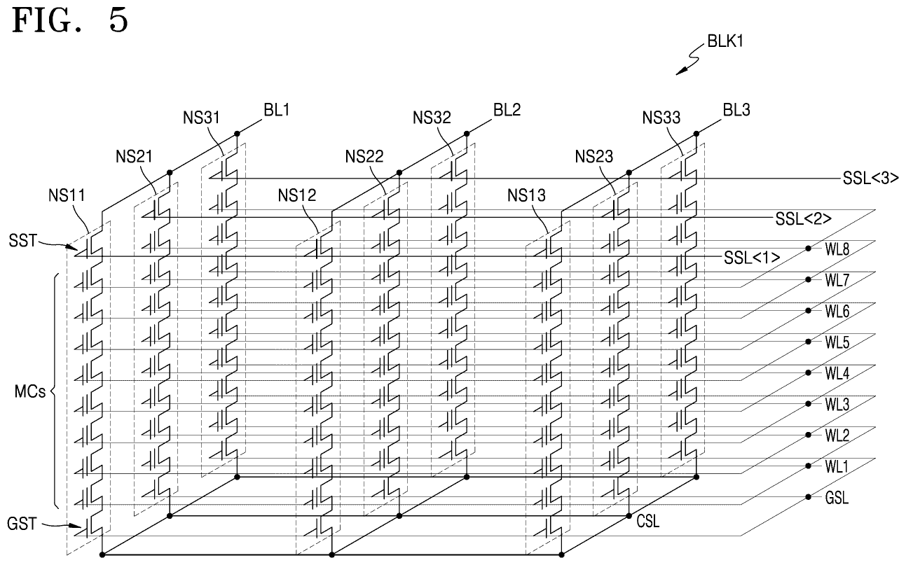

FIG. 5 is an equivalent circuit diagram of a memory block according to one or more implementations.

The memory block illustrated in FIG. 5 is an example of one of the plurality of memory blocks BLK1 to BLKz described above with reference to FIG. 4 and illustrates a first memory block BLK1. Hereinafter, implementations will be described in detail using the first memory block BLK1 as an example. For convenience of explanation, the first memory block BLK1 may be referred to interchangeably as a memory block BLK1. The memory block BLK1 represents a 3-dimensional memory block formed in a 3-dimensional structure on a substrate. A plurality of memory cell strings included in the memory block BLK1 may be formed in a direction perpendicular to the substrate.

Referring to FIG. 5, the memory block BLK1 may include cell strings NS11 to NS33, word lines WL1 to WL8, bit lines BL1 to BL3, the ground select line GSL, the string select lines SSL<1> to SSL<3>, and a common source line CSL. Although FIG. 5 illustrates that each of the cell strings NS11 to NS33 includes eight memory cells MCs respectively connected to eight word lines WL1 to WL8, it is merely an example to aid understanding, and implementations are not limited thereto.

Each cell string (e.g., NS11) may include a string select transistor SST, a plurality of memory cells MCs, and a ground select transistor GST that are connected in series. The string select transistor SST is connected to a corresponding string select line SSL<1>. The memory cells MCs are connected to corresponding word lines WL1 to WL8, respectively. The ground select transistor GST is connected to the ground select line GSL. String select transistors SST are respectively connected to corresponding bit lines BL1 to BL3, and the ground select transistor GST is connected to the common source line CSL.

In the memory block BLK1, the word lines WL1 to WL8 are commonly connected to memory cell transistors included in one layer. Memory cell transistors included in one layer are supplied with the same word line voltage. The plurality of string select transistors SST formed in one layer are connected to the plurality of string select lines SSL<1> to SSL<3>. The ground select transistors GST are controlled simultaneously. In other words, the ground select transistors GST included in the memory block BLK1 are controlled by the ground select line GSL.

According to some implementations, each cell string may be provided with one or more dummy memory cells between the string select transistor SST and the memory cells MC. Each cell string may be provided with one or more dummy memory cells between the ground select transistor GST and the memory cells MC. Each cell string may be provided with one or more dummy memory cells between the memory cells MC. Dummy memory cells have the same structure as the memory cells MC and may not be programmed (e.g., program-inhibited) or may be programmed differently from the memory cells MC. For example, when the memory cells MC are programmed to have two or more threshold voltage distributions, dummy memory cells may be programmed to have one threshold voltage distribution range or fewer threshold voltage distributions than the memory cells MC.

FIG. 6 is a diagram illustrating the address decoder 220, the first ground transistor circuit 211_1, the first pass transistor circuit 211_2, and the first memory block BLK1, according to one or more implementations.

Referring to FIG. 6, the memory device 10 may include the first ground transistor circuit 211_1 and the first pass transistor circuit 211_2 connected between the address decoder 220 and the first memory block BLK1. The memory block BLK1 may include the ground select line GSL, a plurality of word lines, that is, the first to m-th word lines WL1 to WLm, a plurality of dummy word lines DWL<1> to DWL<4>, and the plurality of string select lines SSL<1> to SSL<3>, where m is a positive integer.

In the memory device 10 of FIG. 6, the memory block BLK1 may further include first to fourth dummy word lines DWL<1> to DWL<4>. A first dummy word line DWL<1> and a second dummy word line DWL<2> may be arranged between the ground select line GSL and the first word line WL1, and a third dummy word line DWL<3> and a fourth word line DWL<4> may be arranged between an m-th word line WLm and a first string select line SSL<1>. According to some implementations, the memory block BLK1 may include at least one of the first to fourth dummy word lines DWL<1> to DWL<4>. Depending on implementations, the number of dummy word lines included in the memory block BLK1 may vary. The plurality of dummy word lines DWL<1> to DWL<4> can be arranged between the plurality of string select lines SSL<1> to SSL<3> and the plurality of word lines WL1 to WLm or between the ground select line GSL and the plurality of word lines WL1 to WLm. In other words, the plurality of dummy word lines can be arranged: (1) between the plurality of string select lines and the plurality of word lines, or (2) between the ground select line and the plurality of word lines, or (3) some of dummy word lines being between the plurality of string select lines and the plurality of word lines, while some of dummy word lines being between the ground select line and the plurality of word lines.

The address decoder 220 may include a block decoder 221 and a driving signal line decoder 222. The first ground transistor circuit 211_1 may include a plurality of ground transistors GTRg, GTRd1 to GTRd4, and GTR1 to GTRm, and the first pass transistor circuit 211_2 may include a plurality of pass transistors TRg, TRd1 to TRd4, TR1 to TRm, and TRs1 to TRs3, where m is a positive integer. The first pass transistor circuit 211_2 may be provided for each of memory blocks (BLK1 to BLKz of FIG. 4), and the block decoder 221 and the driving signal line decoder 222 may be provided in common for one or more memory blocks (BLK1 to BLKz of FIG. 4).

The block decoder 221 may be connected to the first ground transistor circuit 211_1 through a first block select signal line and may be connected to the first pass transistor circuit 211_2 through a second block select signal line. The first block select signal line may be connected to gates of the plurality of ground transistors GTRg, GTRd1 to GTRd4, and GTR1 to GTRm. Also, the second block select signal line may be connected to gates of the plurality of pass transistors TRg, TRd1 to TRd4, TR1 to TRm, and TRs1 to TRs3. For example, when the first memory block BLK1 is not selected and a first block select signal BLKSEL connected to the first block select signal line is activated, the plurality of ground transistors GTRg, GTRd1 to GTRd4, and GTR1 to GTRm may be turned on and driven, and a pass transistor circuit 211_2 may be turned off in response to a second block select signal BLKWL provided through the second block select signal line. For example, when the first memory block BLK1 is selected and the second block select signal BLKWL provided through the second block select signal line is activated, the plurality of pass transistors TRg, TRd1 to TRd4, TR1 to TRm, and TRs1 to TRs3 may be turned on and driven, and the first ground transistor circuit 211_1 may be turned off.

According to an implementation, the phases of the first block select signal BLKSEL and the second block select signal BLKWL may be opposite to each other. For example, when the logic level of the first block select signal BLKSEL is a high level, the logic level of the second block select signal BLKWL may be a low level, and, when the logic level of the first block select signal BLKSEL is a low level, the logic level of the second block select signal BLKWL may be a high level.

The driving signal line decoder 222 may be connected to the first ground transistor circuit 211_1 through the select lines S1 to Sm, dummy select lines DS<1> to DS<4>, and the ground select line driving signal line GS and may be connected to the first pass transistor circuit 211_2 through string select line driving signal lines SS<1> to SS<3>, the select lines S1 to Sm, the dummy select lines DS<1> to DS<4>, and the ground select line driving signal line GS. In detail, the select lines S1 to Sm, the dummy select lines DS<1> to DS<4>, and the ground select line driving signal line GS may be respectively connected to one ends, e.g., sources or drains, of the plurality of ground transistors GTRg, GTRd1 to GTRd4, and GTR1 to GTRm, and the other ends, e.g., drains or sources, of the plurality of ground transistors GTRg, GTRd1 to GTRd4, and GTR1 to GTRm may each be applied with the ground voltage GND. Also, one end of a plurality of grounding transistors GTRg, GTRd1 to GTRd4, and GTR1 to GTRm may be connected to some pass transistors TRd1 to TRd4, TR1 to TRm, and TRg of the plurality of pass transistors TRg, TRd1 to TRd4, TR1 to TRm, and TRs1 to TRs3. The string select line driving signal lines SS<1> to SS<3>, the select lines S1 to Sm, the dummy select lines DS<1> to DS<4>, and the ground select line driving signal line GS may be respectively connected to one ends, e.g., sources or drains, of the plurality of pass transistors TRg, TRd1 to TRd4, TR1 to TRm, and TRs1 to TRs3.

The first ground transistor circuit 211_1 may be connected to the first memory block BLK1 through the ground select line GSL, the plurality of word lines, that is, the first to m-th word lines WL1 to WLm and a plurality of dummy word lines DWL<1> to DWL<4>. One end of a ground transistor GTRg may be connected to the ground select line driving signal line GS, a gate of the ground transistor GTRg may be provided with the first block select signal BLKSEL, and the other end of the ground transistor GTRg may be provided with the ground voltage GND. One ends of ground transistors GTR1 to GTRm may be connected to the select lines S1 to Sm, gates of the ground transistors GTR1 to GTRm may be provided with the first block select signal BLKSEL, and the other ends of the ground transistors GTR1 to GTRm may be provided with the ground voltage GND. One end of ground transistors GTRd1 to GTRd4 may be connected to the dummy select line driving signal lines DS<1> to DS<4>, gates of the ground transistors GTRd1 to GTRd4 may be provided with the first block select signal BLKSEL, and the other ends of the ground transistors GTRd1 to GTRd4 may be provided with the ground voltage GND. For example, when the first block select signal BLKSEL is activated, the ground transistors GTRg, GTRd1 to GTRd4, and GTR1 to GTRm may provide driving signals, which are provided through the select lines S1 to Sm, the dummy select line driving signal lines DS<1> to DS<4>, and the ground select line driving signal line GS, to the first to m-th word lines WL1 to WLm, the dummy word lines DWL<1> to DWL<4>, and the ground select line GSL, respectively.

The first pass transistor circuit 211_2 may be connected to the first memory block BLK1 through the ground select line GSL, the plurality of word lines, that is, the first to m-th word lines WL1 to WLm, the plurality of dummy word lines DWL<1> to DWL<4>, and the string select lines SSL<1> to SSL<3>. The pass transistor TRg may be connected between the ground select line driving signal line GS and the ground select line GSL. A plurality of pass transistors TR1 to TRm may be respectively connected between the select lines S1 to Sm and a plurality of word lines, that is, the first to m-th word lines WL1 to WLm. Pass transistors TRd1 to TRd4 may be respectively connected between the dummy select line driving signal lines DS<1> to DS<4> and the plurality of dummy word lines DWL<1> to DWL<4>. Pass transistors TRs1 to TRs3 may be respectively connected between the string select line driving signal lines SS<1> to SS<3> and the string select lines SSL<1> to SSL<3>. Gates of the pass transistors TRg, TRd1 to TRd4, TR1 to TRm, and TRs1 to TRs3 may each be provided with the second block select signal BLKWL. For example, when the second block select signal BLKWL is activated, the pass transistors TRg, TRd1 to TRd4, TR1 to TRm, and TRs1 to TRs3 may provide driving signals, which are provided through the string select line driving signal lines SS<1> to SS<3>, the select lines S1 to Sm, the dummy select line driving signal lines DS<1> to DS<4>, and the ground select line driving signal line GS to the string select lines SSL<1> to SSL<3>, the first to m-th word lines WL1 to WLm, the dummy word lines DWL<1> to DWL<4>, and the ground select line GSL, respectively.

According to an implementation, the number of the ground transistors GTRg, GTRd1 to GTRd4, and GTR1 to GTRm included in the first ground transistor circuit 211_1 may be smaller than the number of the pass transistors TRg, TRd1 to TRd4, TR1 to TRm, and TRs1 to TRs3 included in the first pass transistor circuit 211_2. In other words, the first ground transistor circuit 211_1 may not include ground transistors connected to the plurality of string select lines SSL<1> to SSL<3>.

Therefore, the first ground transistor circuit 211_1 may not include a ground transistor in the plurality of string select lines SSL<1> to SSL<3>. Instead, the first ground transistor circuit 211_1 may control the ground transistors GTRd1 to GTRd4 and the ground transistors GTR1 to GTRm respectively connected to the first to fourth dummy word lines DWL<1> to DWL<4> and the first to m-th word lines WL1 to WLm. Therefore, the first ground transistor circuit 211_1 may reduce the number of ground transistors and reduce the chip size of the memory device 10.

According to an implementation, the number of the ground transistors GTRg, GTRd1 to GTRd4, and GTR1 to GTRm included in the first ground transistor circuit 211_1 may be equal to the number of the ground transistors GTRg, GTRd1 to GTRd4, and GTR1 to GTRm connected to the plurality of word lines, that is, the first to m-th word lines WL1 to WLm, the plurality of dummy word lines DWL<1> to DWL<4> and the ground select line GSL. The number of the pass transistors TRg, TRd1 to TRd4, TR1 to TRm, and TRs1 to TRs3 included in the first pass transistor circuit 211_2 may be equal to the number of the pass transistors TRg, TRd1 to TRd4, TR1 to TRm, and TRs1 to TRs3 connected to the plurality of select lines S1 to Sm, the plurality of word lines, that is, the first to m-th word lines WL1 to WLm, the plurality of dummy word lines DWL<1> to DWL<4>, and the ground select line GSL. In other words, the first ground transistor circuit 211_1 may not include ground transistors connected to the plurality of select lines S1 to Sm. The pass transistors TRg, TRd1 to TRd4, TR1 to TRm, and TRs1 to TRs3 are connected to the ground select line GSL, the dummy word lines DWL<1> to DWL<4>, the first to m-th word lines WL1 to WLm, and the string select lines SSL<1> to SSL<3>.

According to an implementation, when the first memory block BLK1 is selected from a plurality of memory blocks (BLK1 to BLKz of FIG. 4), an activated second block select signal BLKWL may be supplied to the first pass transistor circuit 211_2 corresponding to the first memory block BLK1. Conversely, when the first memory block BLK1 of the plurality of memory blocks is not selected, an activated first block select signal BLKSEL may be supplied to the first ground transistor circuit 211_1 corresponding to the first memory block BLK1.

In other words, the string select lines SSL<1> to SSL<3>, the first to m-th word lines WL1 to WLm, the dummy word lines DWL<1> to DWL<4>, and the ground select line GSL of a selected memory block may be connected to the address decoder 220. A ground voltage may be supplied to a fourth dummy word line DWL<4> of an unselected memory block, and the first to m-th word lines WL1 to WLm and the ground select line GSL, and the dummy word lines DWL<1> to DWL<4> of the unselected memory block may be floated.

Although the first ground transistor circuit 211_1 is illustrated in FIG. 6, the configuration of the first ground transistor circuit 211_1 may be applied equally to a second ground transistor circuit 212_1 to a z-th ground transistor circuit 21z_1 illustrated in FIG. 2. Also, although the first pass transistor circuit 211_2 is illustrated in FIG. 6, the configuration of the first pass transistor circuit 211_2 may be equally applied to a second pass transistor circuit 212_2 to a z-th pass transistor circuit 21z_2 illustrated in FIG. 2.

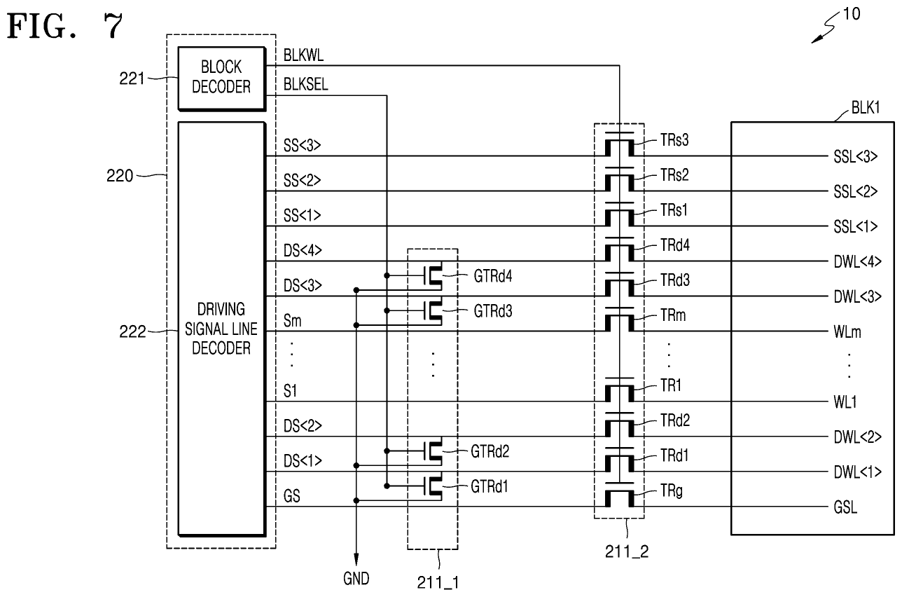

It is to be noted that the ground select line GSL, the plurality of word lines (e.g., the first to m-th word lines WL1 to WLm), the plurality of dummy word lines DWL<1> to DWL<4>, and the string select lines SSL<1> to SSL<3> can be referred to as control lines in the present disclosure. The control lines can include a first group of control lines and a second group of control lines. The first group of control lines can include the control lines that are connected to the ground transistors, while the second group of control lines are include the remaining control lines that are not connected to the ground transistors. For example, in the example implementation shown in FIG. 6, the first group of control lines can include the plurality of dummy word lines DWL<1> to DWL<4>, while the second group of control lines can include the string select lines SSL<1> to SSL<3>, the plurality of word lines (e.g., the first to m-th word lines WL1 to WLm), and and the ground select line GSL. In another example, as shown in FIG. 7 below, the first group of control lines can include the plurality of word lines (e.g., the first to m-th word lines WL1 to WLm), the plurality of dummy word lines DWL<1> to DWL<4>, and the ground select line GSL, while the second group of control lines can include the string select lines SSL<1> to SSL<3>. In yet another example, as shown in FIG. 8 below, the first group of control lines can include a single dummy word DWL<4> that is connected to the ground transistor GTRd4, while the second group of control lines include the remaining control lines, e.g., the plurality of word lines (e.g., the first to m-th word lines WL1 to WLm), the dummy word lines DWL<1> to DWL<3>, and the string select lines SSL<1> to SSL<3>, and the ground select line GSL.

In some implementations, although not shown in FIG. 6, at least one of the ground transistors GTR is connected to at least one of the string select lines SSL, and a number of the ground transistors GTR is smaller than a number of the plurality of string select lines SSL. For examples, the ground transistors GTR can be connected to some of the string select lines SSL, but not to all of them.

FIG. 7 is a diagram illustrating an address decoder, a first ground transistor circuit, a first pass transistor circuit, and a first memory block, according to one or more implementations. Descriptions identical to those given above with reference to FIG. 6 will be omitted.

Referring to FIG. 7, the first ground transistor circuit 211_1 may include the plurality of ground transistors GTRd1 to GTRd4. Unlike the first ground transistor circuit 211_1 illustrated in FIG. 6, one ends of the plurality of ground transistors GTRd1 to GTRd4 are connected only to the dummy select line driving signal lines DS<1> to DS<4>.

The first ground transistor circuit 211_1 may be connected to the first memory block BLK1 through the plurality of dummy word lines DWL<1> to DWL<4>.

One end of ground transistors GTRd1 to GTRd4 may be connected to the dummy select line driving signal lines DS<1> to DS<4>, gates of the ground transistors GTRd1 to GTRd4 may be provided with the first block select signal BLKSEL, and the other ends of the ground transistors GTRd1 to GTRd4 may be provided with the ground voltage GND.

According to an implementation, the first ground transistor circuit 211_1 may not include ground transistors connected to the plurality of string select lines SSL<1> to SSL<3>, the plurality of word lines (e.g., the first to m-th word lines WL1 to WLm), and the ground select line GSL. Instead, the first ground transistor circuit 211_1 may control the ground transistors GTRd1 to GTRd4 connected to the first to fourth dummy word lines DWL<1> to DWL<4>. Therefore, the first ground transistor circuit 211_1 may reduce the number of ground transistors and reduce the chip size of the memory device 10.

FIG. 8 is a diagram illustrating the address decoder 220, the first ground transistor circuit 211_1, the first pass transistor circuit 211_2, and the first memory block BLK1, according to one or more implementations. Descriptions identical to those given above with reference to FIG. 6 will be omitted.

Referring to FIG. 8, the first ground transistor circuit 211_1 may include a ground transistor GTRd4. Unlike the first ground transistor circuit 211_1 illustrated in FIG. 6, one end of the ground transistor GTRd4 is connected only to a dummy select line driving signal line DS<4>.

The first ground transistor circuit 211_1 may be connected to the first memory block BLK1 through the fourth dummy word line DWL<4>.

One end of a ground transistor GTRd4 may be connected to the dummy select line driving signal line DS<4>, a gate of the ground transistor GTRd4 may be provided with the first block select signal BLKSEL, and the other end of the ground transistor GTRd4 may be provided with the ground voltage GND.

According to an implementation, the first ground transistor circuit 211_1 may not include ground transistors connected to the plurality of string select lines SSL<1> to SSL<3>, first to third dummy word lines DWL<1> to DWL<3>, the plurality of word lines, that is, the first to m-th word lines WL1 to WLm, and the ground select line GSL. Instead, the first ground transistor circuit 211_1 may control the ground transistor GTRd4 connected to the fourth dummy word line DWL<4>. Therefore, the first ground transistor circuit 211_1 may reduce the number of ground transistors and reduce the chip size of the memory device 10.

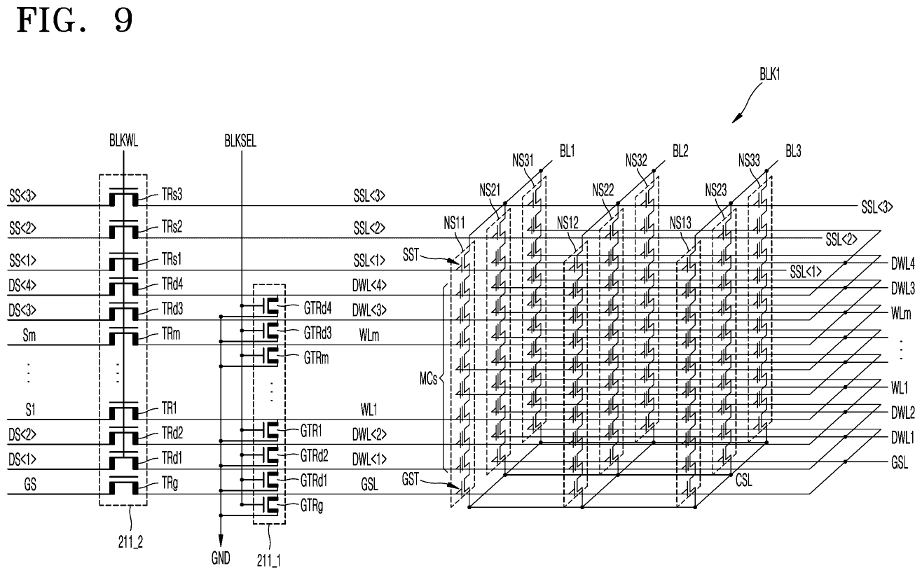

FIG. 9 is a circuit diagram exemplifying the first ground transistor circuit 211_1, the first pass transistor circuit 211_2, and the first memory block BLK1 according to one or more implementations.

Referring to FIG. 9, the first ground transistor circuit 211_1 may correspond to the implementation of FIG. 6, and the first pass transistor circuit 211_2 may correspond to the implementation of FIG. 6. According to an implementation, the first memory block BLK1 may correspond to an implementation of the first memory block BLK1 illustrated in FIGS. 5 and 6.

The first memory block BLK1 may include the plurality of cell strings NS11 to NS33, the plurality of string select lines SSL<1> to SSL<3>, the plurality of word lines, that is, the first to m-th word lines WL1 to WLm, the plurality of dummy word lines DWL<1> to DWL<4>, the plurality of bit lines BL1 to BL3, the ground select line GSL, and the common source line CSL. Here, the number of NAND strings, the number of string select lines, the number of word lines, the number of dummy word lines, the number of bit lines, and the number of ground select lines may vary depending on implementation.

NAND strings NS11, NS21, and NS31 are provided between a first bit line BL1 and the common source line CSL, and NAND strings NS12, NS22, and NS32 are provided between a second bit line BL2 and the common source line CSL. Each NAND string (e.g., NS33) may include the string select transistor SST, the plurality of memory cells MCs, and the ground select transistor GST that are connected in series.

The string select transistor SST is coupled to corresponding string select lines SSL<1> to SSL<3>. The plurality of memory cells MCs are connected to corresponding word lines, i.e., the first to m-th word lines WL1 to WLm, and corresponding dummy word lines DWL<1> to DWL<4>, respectively. The ground select transistor GST is connected to the ground select line GSL corresponding thereto. String select transistors SST are respectively connected to corresponding bit lines BL1 to BL3, and the ground select transistor GST is connected to the common source line CSL.

According to an implementation, word lines (e.g., WL1) of the same height (i.e., arranged at the same level) are commonly connected to one another, and the select lines S1 to Sm are separated from one another. Although FIG. 8 illustrates that three string select lines SSL<1> to SSL<3> share word lines of the same height, the present disclosure is not limited thereto. For example, two string select lines may share word lines of the same height. In another example, four string select lines may share word lines of the same height.

The first ground transistor circuit 211_1 may include the ground transistor GTRg connected to the ground select line GSL, the ground transistors GTR1 to GTRm respectively connected to the first to m-th word lines WL1 to WLm, and the ground transistors GTRd1 to GTRd4 respectively connected to the dummy word lines DWL<1> to DWL<4>. For example, one end of the ground transistor GTRg may be connected to the ground select line driving signal line GS or the ground select line GSL, a gate of the ground transistor GTRg may be provided with the first block select signal BLKSEL, and the other end of the ground transistor GTRg may be provided with the ground voltage GND. One ends of the ground transistors GTR1 to GTRm may be connected to the select lines S1 to Sm or the first to m-th word lines WL1 to WLm, gates of the ground transistors GTR1 to GTRm may be provided with the first block select signal BLKSEL, and the other ends of the ground transistors GTR1 to GTRm may be provided with the ground voltage GND. One ends of the ground transistors GTRd1 to GTRd4 may be connected to the dummy select line driving signal lines DS<1> to DS<4> or the dummy word lines DWL<1> to DWL<4>, gates of the ground transistors GTRd1 to GTRd4 may be provided with the first block select signal BLKSEL, and the other ends of the ground transistors GTRd1 to GTRd4 may be provided with the ground voltage GND. The ground transistors GTRg, GTRd1 to GTRd4, and GTR1 to GTRm may be turned on according to the first block select signal BLKSEL provided along the first block select signal line and may provide driving signals, which are provided through the select lines S1 to Sm, the dummy select line driving signal lines DS<1> to DS<4>, and the ground select line driving signal line GS, to the first to m-th word lines WL1 to WLm, the dummy word lines DWL<1> to DWL<4>, and the ground select line GSL, respectively.

The first pass transistor circuit 211_2 may include the pass transistor TRg connected to a ground select line GSL, the pass transistors TR1 to TRm respectively connected to first to m-th word lines WL1 to WLm, the pass transistors TRd1 to TRd4 respectively connected to dummy word lines DWL<1> to DWL<4>, and the pass transistors TRs1 to TRs3 respectively connected to string select lines SSL<1> to SSL<3>. The pass transistors TRg, TRd1 to TRd4, TR1 to TRm, and TRs1 to TRs3 may be turned on according to the second block select signal BLKWL provided along the second block select signal line and may provide driving signals, which are provided through the string select line driving signal lines SS<1> to SS<3>, the select lines S1 to Sm, the dummy select line driving signal lines DS<1> to DS<4>, and the ground select line driving signal line GS, to the string select lines SSL<1> to SSL<3>, the first to m-th word lines WL1 to WLm, the dummy word lines DWL<1> to DWL<4>, and the ground select line GSL, respectively.

According to an implementation, the number of the ground transistors GTRg, GTRd1 to GTRd4, and GTR1 to GTRm included in the first ground transistor circuit 211_1 may be smaller than the number of the pass transistors TRg, TRd1 to TRd4, TR1 to TRm, and TRs1 to TRs3 included in the first pass transistor circuit 211_2.

According to an implementation, the first ground transistor circuit 211_1 may not include a ground transistor in the plurality of string select lines SSL<1> to SSL<3>. Instead, the ground transistors GTRd1 to GTRd4 and the ground transistors GTR1 to GTRm connected to the first to fourth dummy word lines DWL<1> to DWL<4> and the first to m-th word lines WL1 to WLm may be controlled. Therefore, the first ground transistor circuit 211_1 may reduce the number of ground transistors and reduce the chip size of the memory device 10.

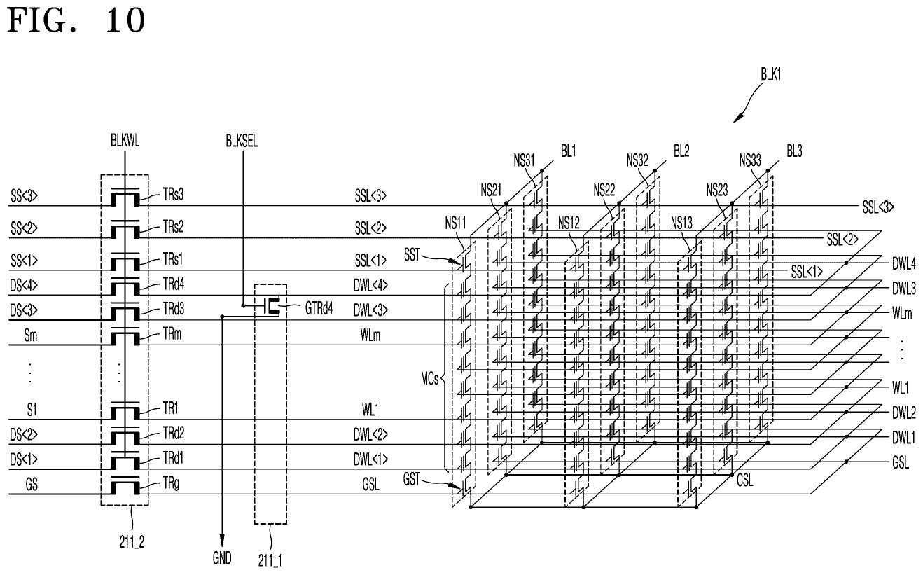

FIG. 10 is a circuit diagram exemplifying the first ground transistor circuit 211_1, the first pass transistor circuit 211_2, and the first memory block BLK1 according to one or more implementations. Descriptions identical to those given above with reference to FIG. 9 will be omitted.

Referring to FIG. 10, the first ground transistor circuit 211_1 may correspond to one implementation of FIG. 8, and the first pass transistor circuit 211_2 may correspond to one implementation of FIG. 8. According to an implementation, the first memory block BLK1 may correspond to an implementation of the first memory block BLK1 illustrated in FIGS. 5 and 8.

The first ground transistor circuit 211_1 may include the ground transistor GTRd4 connected to the fourth dummy word line DWL<4>. For example, one end of the ground transistor GTRd4 may be connected to a fourth dummy select line driving signal line DS<4> or the fourth dummy word line DWL<4>, a gate of the ground transistor GTRd4 may be provided with the first block select signal BLKSEL, and the other end of the ground transistor GTRd4 may be provided with the ground voltage GND. The ground transistor GTRd4 may be turned on according to the first block select signal BLKSEL provided along the first block select signal line and may provide a driving signal provided through the fourth dummy select line driving signal line DS<4> to the fourth dummy word line DWL<4>.

According to an implementation, the number of ground transistors GTRd4 included in the first ground transistor circuit 211_1 may be smaller than the number of the pass transistors TRg, TRd1 to TRd4, TR1 to TRm, and TRs1 to TRs3 included in the first pass transistor circuit 211_2.

According to an implementation, the first ground transistor circuit 211_1 may not include ground transistors connected to the plurality of string select lines SSL<1> to SSL<3>, first to third dummy word lines DWL<1> to DWL<3>, the plurality of word lines, that is, the first to m-th word lines WL1 to WLm, and the ground select line GSL. Instead, the first ground transistor circuit 211_1 may control the ground transistor GTRd4 connected to the fourth dummy word line DWL<4>. Therefore, the first ground transistor circuit 211_1 may reduce the number of ground transistors and reduce the chip size of the memory device 10.

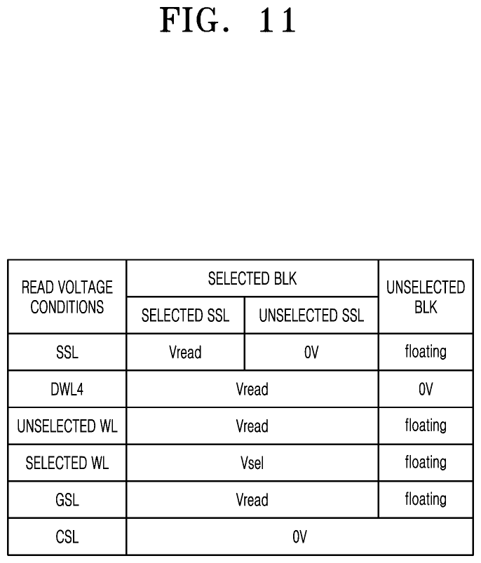

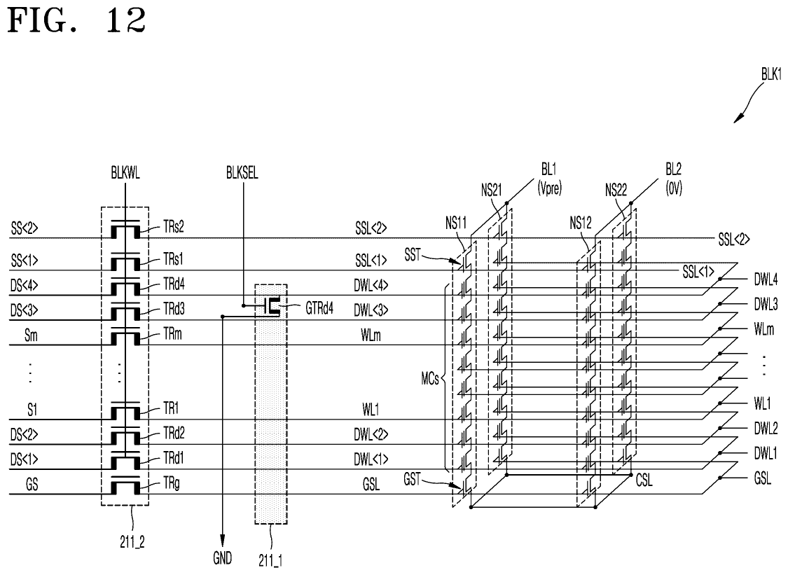

FIG. 11 is a table illustrating voltage conditions during a read operation of a memory device, according to one or more implementations. FIG. 12 is a circuit diagram showing the operation of the first pass transistor circuit 211_2, the first ground transistor circuit 211_1, and the first memory block BLK1 during a read operation of a memory device, according to one or more implementations.

Referring to FIGS. 11 and 12 together, it will be assumed that, when the memory block BLK1 is selected, the first string select line SSL<1> is unselected, a second string select line SSL<2> is selected, the first bit line BL1 is selected, and the second bit line BL2 is unselected. Here, the term ‘unselected’may mean that one is not selected.

In this case, all of the ground transistors GTRg, GTRd1 to GTRd4, and GTR1 to GTRm included in the first ground transistor circuit 211_1 may be turned off, and all of the pass transistors TRg, TRd1 to TRd4, TR1 to TRm, and TRs1 to TRs2 included in the first pass transistor circuit 211_2 may be turned on. A read voltage Vread may be applied to a selected second string select line SSL<2>, and a ground voltage (e.g., 0V) may be applied to an unselected first string select line SSL<1>. A pre-charge voltage Vpre may be applied to a selected first bit line BL1, and the ground voltage (e.g., 0V) may be applied to an unselected second bit line BL2. The read voltage Vread may be applied to the fourth dummy word line DWL<4>, unselected word lines, and the ground select line GSL, a select voltage Vsel may be applied to selected word lines, and the ground voltage e.g., 0 V may be applied to the common source line CSL.

Referring to FIGS. 11 and 12, it will be assumed that, when the memory block BLK1 is unselected, the first string select line SSL<1> is unselected, a second string select line SSL<2> is selected, the first bit line BL1 is selected, and the second bit line BL2 is unselected. In this case, only the ground transistors GTRg, GTRd1 to GTRd4, and GTR1 to GTRm included in the first ground transistor circuit 211_1 may be turned on, and the pass transistors TRg, TRd1 to TRd4, TR1 to TRm, and TRs1 to TRs2 included in the first pass transistor circuit 211_2 may be turned off. In one or more implementations, if the first ground transistor circuit 211_1 include the ground transistor GTRd4, the first string select line SSL<1> and the second string select line SSL<2> may be floated, and the first to m-th word lines WL1 to WLm, the first to third dummy word lines DWL<1> to DWL<3> and the ground select line GSL may be floated. However, the ground voltage (e.g., 0V) may be applied to the fourth dummy word line DWL<4> and the common source line CSL.

In other words, as illustrated in FIG. 12, the first ground transistor circuit 211_1 according to one or more implementations may not include ground transistors connected to the plurality of string select lines SSL<1> to SSL<3>, the first to third dummy word lines DWL<1> to DWL<3>, the plurality of word lines, i.e., the first to m-th word lines WL1 to WLm, and the ground select line GSL. Instead, the first ground transistor circuit 211_1 may control the ground transistor GTRd4 connected to the fourth dummy word line DWL<4>. Therefore, the first ground transistor circuit 211_1 may reduce the number of ground transistors and reduce the chip size of the memory device 10. In other one or more implementations, if the first ground transistor circuit 211_1 includes the ground transistor GTRg, when the memory block BLK1 is unselected, the ground voltage (e.g., 0V) may be applied to the ground select line GSL. If the first ground transistor circuit 211_1 includes the ground transistors GTRd1 to GTRd4, when the memory block BLK1 is unselected, the ground voltage (e.g., 0V) may be applied to the first to fourth dummy word lines DWL<1> to DWL<4>. If the first ground transistor circuit 211_1 includes the ground transistors GTR1 to GTRm, when the memory block BLK1 is unselected, the ground voltage (e.g., 0V) may be applied to the first to m-th word lines WL1 to WLm. In other words, if the first ground transistor circuit 211_1 includes the ground transistors GTRg, GTRd1 to GTRd4, and/or GTR1 to GTRm, when the memory block BLK1 is unselected, the ground voltage (e.g., 0V) may be applied to the ground select line GSL, the first to fourth dummy word lines DWL<1> to DWL<4>, and/or the first to m-th word lines WL1 to WLm.

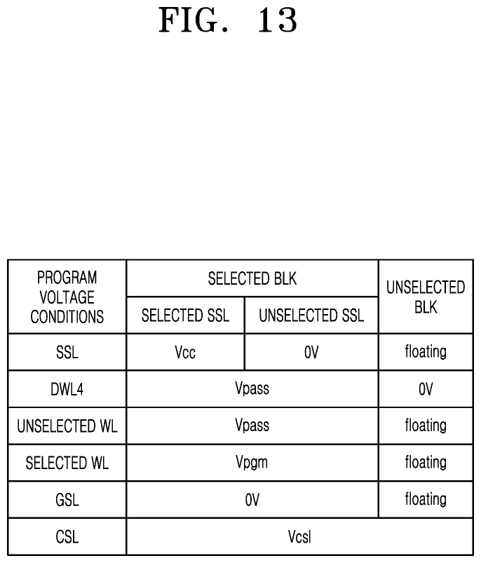

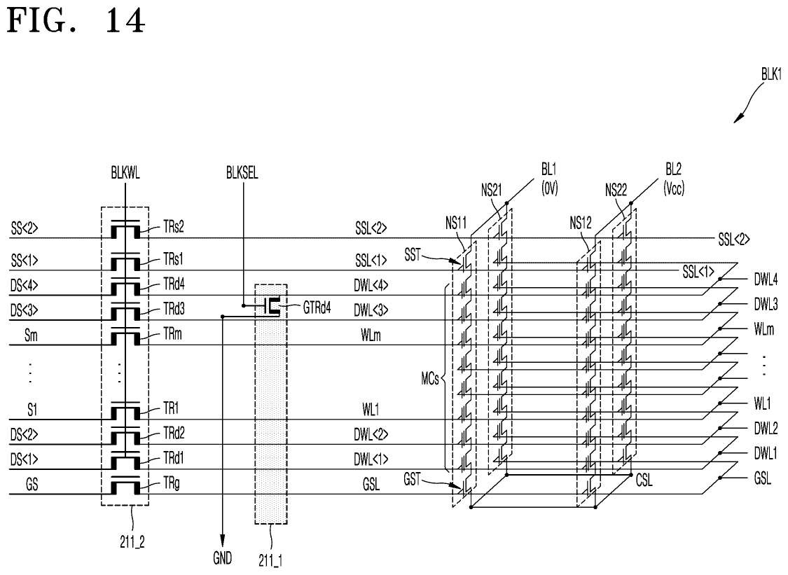

FIG. 13 is a table illustrating voltage conditions during a program operation of a memory device, according to one or more implementations. FIG. 14 is a circuit diagram showing the operation of the first pass transistor circuit 211_2, the first ground transistor circuit 211_1, and the first memory block BLK1 during a program operation of a memory device, according to one or more implementations.

Referring to FIGS. 13 and 14 together, it will be assumed that, when the memory block BLK1 is selected, the first string select line SSL<1> is unselected, a second string select line SSL<2> is selected, the first bit line BL1 is selected, and the second bit line BL2 is unselected.

In this case, all of the ground transistors GTRg, GTRd1 to GTRd4, and GTR1 to GTRm included in the first ground transistor circuit 211_1 and all of the pass transistors TRg, TRd1 to TRd4, TR1 to TRm, and TRs1 to TRs3 included in the first pass transistor circuit 211_2 may be turned on. An internal voltage Vcc may be applied to a selected second string select line SSL<2>, and the ground voltage (e.g., 0V) may be applied to an unselected first string select line SSL<1>. The ground voltage (e.g., 0V) may be applied to a selected first bit line BL1, and the internal voltage Vcc may be applied to an unselected second bit line BL2. A pass voltage Vpass may be applied to unselected word lines and the dummy word lines DWL<1> to DWL<4>, and the program voltage Vpgm may be applied to selected word lines. The ground voltage (e.g., 0V) may be applied to the ground select line GSL, and a common source voltage Vcsl may be applied to the common source line CSL.

Referring to FIGS. 13 and 14, it will be assumed that, when the memory block BLK1 is unselected, the first string select line SSL<1> is unselected, a second string select line SSL<2> is selected, the first bit line BL1 is selected, and the second bit line BL2 is unselected. In this case, only the ground transistors GTRg, GTRd1 to GTRd4, and GTR1 to GTRm included in the first ground transistor circuit 211_1 may be turned on, and the pass transistors TRg, TRd1 to TRd4, TR1 to TRm, and TRs1 to TRs2 included in the first pass transistor circuit 211_2 may be turned off. The first string select line SSL <1> and the second string select line SSL<2> may be floated, and word lines, the first to third dummy word lines DWL<1> to DWL<3> and the ground select line GSL may be floated. However, the ground voltage (e.g., 0V) may be applied to the fourth dummy word line DWL<4>, and the common source voltage Vcsl may be applied to the common source line CSL.

In other words, as illustrated in FIG. 14, the first ground transistor circuit 211_1 according to one or more implementations may not include ground transistors connected to the plurality of string select lines SSL<1> to SSL<3>, the first to third dummy word lines DWL<1> to DWL<3>, the plurality of word lines, i.e., the first to m-th word lines WL1 to WLm, and the ground select line GSL. Instead, the first ground transistor circuit 211_1 may control the ground transistor GTRd4 connected to the fourth dummy word line DWL<4>. Therefore, the first ground transistor circuit 211_1 may reduce the number of ground transistors and reduce the chip size of the memory device 10.

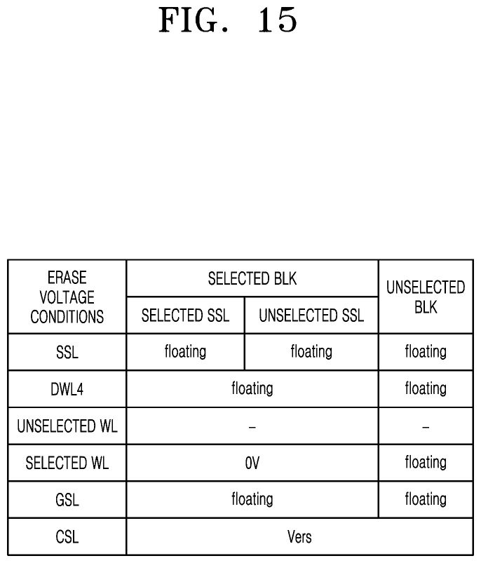

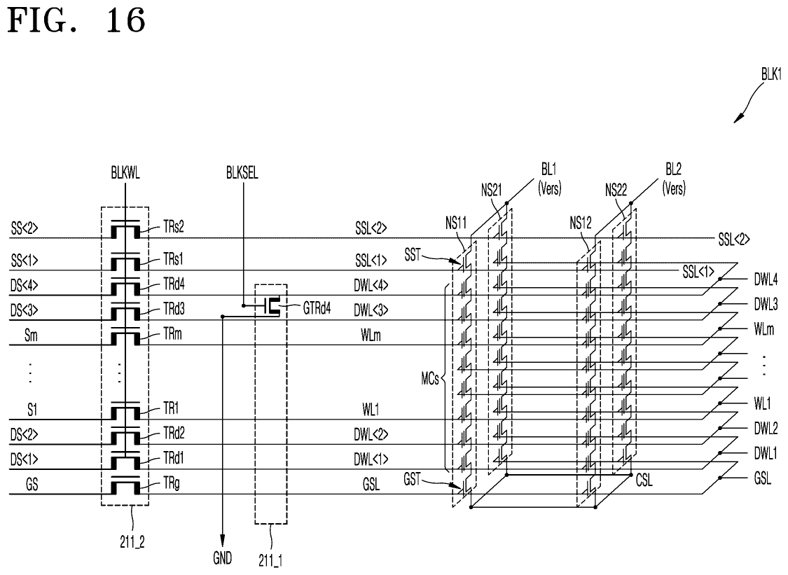

FIG. 15 is a table illustrating voltage conditions during an erase operation of a memory device, according to one or more implementations. FIG. 16 is a circuit diagram showing the operation of the first pass transistor circuit 211_2, the first ground transistor circuit 211_1, and the first memory block BLK1 during an erase operation of a memory device, according to one or more implementations.

Referring to FIGS. 15 and 16 together, it will be assumed that, when the memory block BLK1 is selected, the first string select line SSL<1> is unselected, a second string select line SSL<2> is selected, the first bit line BL1 is selected, and the second bit line BL2 is unselected.

In this case, all of the ground transistors GTRg, GTRd1 to GTRd4, and GTR1 to GTRm included in the first ground transistor circuit 211_1 and all of the pass transistors TRg, TRd1 to TRd4, TR1 to TRm, and TRs1 to TRs2 included in the first pass transistor circuit 211_2 may be turned on. The first string select line SSL <1> and the second string select line SSL<2> may be floated, and the dummy word lines DWL<1> to DWL<4> and the ground select line GSL may be floated. The ground voltage (e.g., 0 V) may be applied to selected word lines. An erase voltage Vers may be applied to the common source line CSL.

Referring to FIGS. 15 and 16, it will be assumed that, when the memory block BLK1 is unselected, the first string select line SSL<1> is unselected, a second string select line SSL<2> is selected, the first bit line BL1 is selected, and the second bit line BL2 is unselected. In this case, only the ground transistors GTRg, GTRd1 to GTRd4, and GTR1 to GTRm included in the first ground transistor circuit 211_1 may be turned on, and the pass transistors TRg, TRd1 to TRd4, TR1 to TRm, and TRs1 to TRs2 included in the first pass transistor circuit 211_2 may be turned off. The first string select line SSL <1> and the second string select line SSL<2> may be floated, and the first to m-th word lines WL1 to WLm, the dummy word lines DWL<1> to DWL<4> and the ground select line GSL may be floated. The erase voltage Vers may be applied to the common source line CSL.

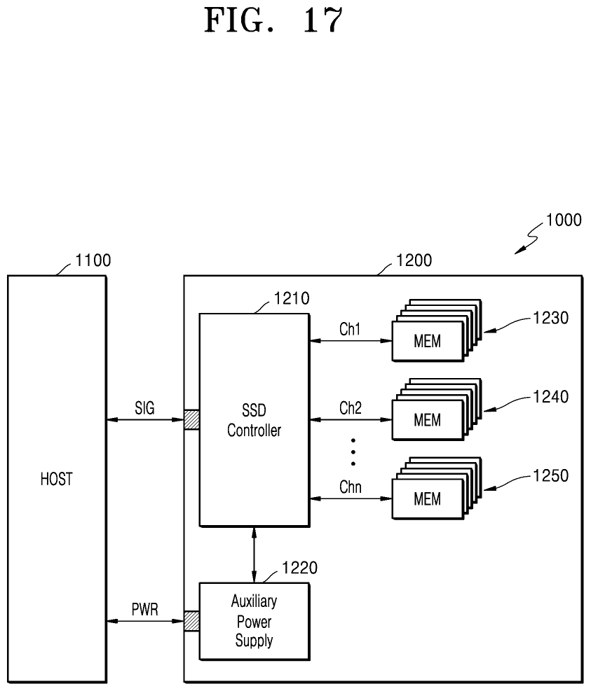

FIG. 17 is a block diagram showing an example in which a memory device according to implementations is applied to a solid state drive (SSD) system 1000.

Referring to FIG. 17, an SSD system 1000 may include a host 1100 and an SSD 2100. The SSD 2100 exchanges signals with the host 1100 through a signal connector and receives power through a power connector. The SSD 2100 may include an SSD controller 1210, an auxiliary power supply device 1220, and a plurality of memory devices 1230, 1240, and 1250. The memory devices 1230, 1240, and 1250 may be vertically stacked NAND flash memory devices. Here, the SSD 2100 may be implemented according to the implementations described above with reference to FIGS. 1 to 16.

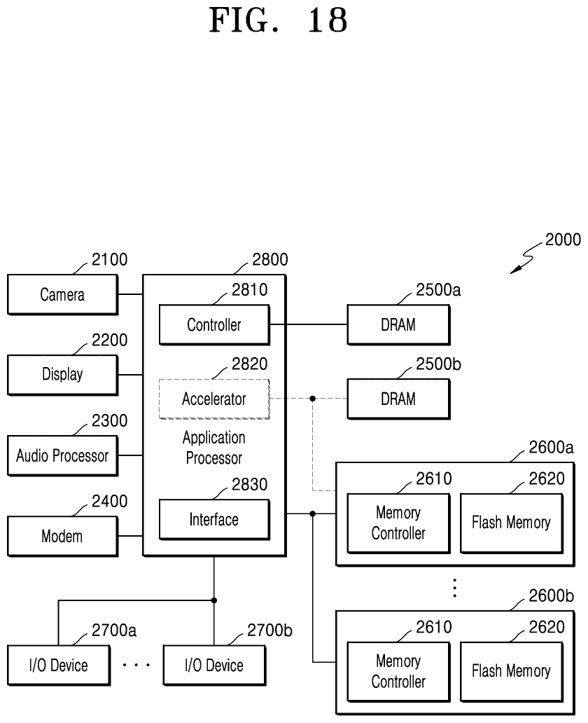

FIG. 18 is a block diagram of a system 2000 for describing an electronic device including a memory device according to one or more implementations.

Referring to FIG. 18, the system 2000 may include a camera 2100, a display 2200, an audio processor 2300, a modem 2400, DRAMs 2500a and 2500b, flash memories 2600a and 2600b, I/O devices 2700a and 2700b, and an application processor (AP) 2800. The system 2000 may be implemented as a laptop computer, a mobile phone, a smartphone, a tablet PC, a wearable device, a healthcare device, or an IoT device. Also, the system 2000 may be implemented as a server or a PC.

The camera 2100 may capture a still image or a video according to a user's control and may store captured image/video data or transmit the captured image/video data to the display 2200. The audio processor 2300 may process audio data included in the flash memories 2600a and 2600b or network content. The modem 2400 may transmit a modulated signal for wired/wireless data transmission/reception to a receiver and the modulated signal may be demodulated by the receiver to restore an original signal. The I/O devices 2700a and 2700b may include devices providing a digital input function and/or digital output function, e.g., a Universal Serial Bus (USB), a storage, a digital camera, a Secure Digital (SD) card, a Digital Versatile Disc (DVD), a network adapter, a touch screen, etc.

The AP 2800 may control the overall operation of the system 2000. The AP 2800 may include a control block 2810, an accelerator block or accelerator chip 2820, and an interface block 2830. The AP 2800 may control the display 2200, such that a part of content stored in the flash memories 2600a and 2600b is displayed on the display 2200. When a user input is received through the I/O devices 2700a and 2700b, the AP 2800 may perform a control operation corresponding to the user input. The AP 2800 may include an accelerator block, which is a circuit dedicated for calculation of artificial intelligence (AI) data, or may include an accelerator chip 2820 separately from the AP 2800. The DRAM 2500b may be additionally provided in the accelerator block or the accelerator chip 2820. The accelerator block is a functional block that specializes in performing a particular function of the AP 2800 and may include a GPU, which is a functional block that specializes in processing graphic data, a neural processing unit (NPU), which is a block that specializes in AI calculation and inference, and a data processing unit (DPU), which is a block that specializes in data transmission. According to an implementation, an image captured by a user through the camera 2100 is signal-processed and stored in the DRAM 2500b, and the accelerator block or accelerator chip 2820 may perform AI data calculation for recognizing data using data stored in the DRAM 2500b and a function used for inference.

The system 2000 may include a plurality of DRAMs 2500a and 2500b. The AP 2800 may set up a DRAM interface protocol and communicate with the DRAMs 2500a and 2500b to control the DRAMs 2500a and 2500b through commands complying with the JEDEC standard and mode register (MRS) setting or to use company-specific functions such as low voltage/high-speed/reliability and a cyclic redundancy check (CRC)/error correction code (ECC) function. For example, the AP 2800 may communicate with the DRAM 2500a through an interface complying with the JEDEC standards such as LPDDR4 and LPDDR5, and the accelerator block or the accelerator chip 2820 may set and use a new DRAM interface protocol to control the DRAM 2500b for an accelerator, which has a greater bandwidth than the DRAM 2500a.

Although FIG. 18 shows only the DRAMs 2500a and 2500b, the present disclosure is not limited thereto. As long as a bandwidth, a response speed, and voltage conditions of the AP 2800 or the accelerator chip 2820 are satisfied, any memory such as a PRAM, an SRAM, an MRAM, an RRAM, an FRAM, or a Hybrid RAM may be used. The DRAMs 2500a and 2500b have relatively smaller latency and bandwidth than the I/O devices 2700a and 2700b or the flash memories 2600a and 2600b. The DRAMs 2500a and 2500b are initialized when the system 2000 is powered on and the OS and application data are loaded thereto, and thus the DRAMs 2500a and 2500b may be used as temporary storages for the OS and the application data or may be used as execution spaces for various software code.

In the DRAMs 2500a and 2500b, four arithmetic operations (i.e., addition, subtraction, multiplication, and division), vector calculations, address calculations, or Fast Fourier Transform (FFT) calculations may be performed. Also, in the DRAMs 2500a and 2500b, a function for an operation used for an inference may be performed. Here, the inference may be performed in a deep learning algorithm using an artificial neural network. The deep learning algorithm may include a training operation for learning a model through various data and an inference operation for recognizing data with the trained model.

The system 2000 may include a plurality of storages or flash memories 2600a and 2600b having a larger capacity than the DRAMs 2500a and 2500b. The accelerator block or accelerator chip 2820 may perform a training operation and an AI data calculation using the flash memories 2600a and 2600b. According to an implementation, the flash memories 2600a and 2600b may include a memory controller 2610 and a flash memory device 2620, and a training operation and an inference AI data calculation performed by the AP 2800 and/or the accelerator chip 2820 may be performed more efficiently by using an arithmetic unit included in the memory controller 2610. The flash memories 2600a and 2600b may store images captured through the camera 2100 or data transmitted through a data network. For example, the flash memories 2600a and 2600b may store Augmented Reality/Virtual Reality content, High Definition (HD) content, or Ultra High Definition (UHD) content.

In the system 2000, the flash memories 2600a and 2600b may include the memory device described above with reference to FIGS. 1 to 17. A memory device may include a memory block including a plurality of string select lines, a plurality of word lines, a ground select line, and a plurality of dummy word lines arranged between the plurality of string select lines and the plurality of word lines or between the ground select line and the plurality of word lines, a pass transistor circuit including a plurality of pass transistors respectively connected to the plurality of string select lines, the plurality of word lines, and the plurality of dummy word lines of the memory block and driven when a memory block is selected, and a ground transistor circuit including a plurality of ground transistors respectively connected to some of the plurality of string select lines, the plurality of word lines, and the plurality of dummy word lines of the memory block and driven when a memory block is not selected. In the memory device, the number of ground transistors included in a memory block may be smaller than the number of string select lines.

Also, the ground transistor circuit may connect the string select lines to a gate of a ground transistor of one of the plurality of dummy word lines without connecting the ground transistor to the string select lines. In other words, the ground transistor circuit may reduce the number of ground transistors and reduce the chip size of the memory device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory block comprising a plurality of cell strings respectively configured to be selected by a plurality of string select lines, wherein each cell string of the plurality of cell strings is connected to a plurality of word lines stacked in a vertical direction;
a pass transistor circuit comprising a plurality of pass transistors respectively connected to the plurality of string select lines and the plurality of word lines, wherein the plurality of pass transistors are configured to be turned on based on the memory block being selected; and
a ground transistor circuit comprising a plurality of ground transistors respectively connected to the plurality of word lines, wherein the plurality of ground transistors are configured to be turned on based on the memory block being unselected,
wherein a number of the ground transistors is smaller than a number of the plurality of string select lines.

2. The memory device of claim 1, wherein the each cell string of the plurality of cell strings is connected to dummy word lines between the plurality of word lines and a ground select line and the ground select line,
the plurality of pass transistors are respectively connected to the dummy word lines and the ground select line, and
the ground transistor circuit further comprises at least one ground transistor connected to at least one of the dummy word lines.

3. The memory device of claim 1, wherein the each cell string of the plurality of cell strings is connected to dummy word lines between the plurality of word lines and the plurality of string select lines,
the plurality of pass transistors are respectively connected to the dummy word lines, and
the ground transistor circuit further comprises at least one ground transistor connected to at least one of the dummy word lines.

4. The memory device of claim 1, wherein a number of the plurality of ground transistors of the ground transistor circuit is smaller than a number of the plurality of pass transistors of the pass transistor circuit.

5. The memory device of claim 1, wherein an end of at least one of the plurality of ground transistors of the ground transistor circuit is configured to be applied with a ground voltage.

6. The memory device of claim 1, wherein:
based on the memory block being selected, the pass transistor circuit is configured to drive, in response to a first phase of a first block select signal, the plurality of string select lines and the plurality of word lines, and the ground transistor circuit is configured to be turned off in response to a first phase of a second block select signal; and
based on the memory block being unselected, the ground transistor circuit is configured to drive, in response to a second phase of the second block select signal, the plurality of word lines, and the pass transistor circuit is configured to be turned off in response to a second phase of the first block select signal.

7. The memory device of claim 6, wherein the first phase of the first block select signal is opposite to the first phase of the second block select signal.

8. The memory device of claim 6, wherein:
during a read operation of the memory block, based on the memory block being unselected, the plurality of word lines are configured to be applied with a ground voltage level, and the plurality of string select lines are configured to be floated.

9. The memory device of claim 6, wherein:
during a program operation of the memory block, based on the memory block being unselected, the plurality of word lines are configured to be applied with a ground voltage level, and the plurality of string select lines are configured to be floated.

10. A memory device comprising:
a memory block formed on a first semiconductor layer and comprising a plurality of cell strings respectively selected by a plurality of string select lines, wherein each cell string comprises a plurality of memory cells respectively connected to a plurality of word lines stacked in a vertical direction;
a plurality of dummy word lines formed on the first semiconductor layer and positioned between the plurality of string select lines and a ground select line;
a pass transistor circuit formed on a second semiconductor layer positioned below the first semiconductor layer in the vertical direction, the pass transistor circuit comprising a plurality of pass transistors respectively connected to the plurality of string select lines, the plurality of word lines, the plurality of dummy word lines and the ground select line, wherein the plurality of pass transistors are configured to be turned on based on the memory block being selected; and
a ground transistor circuit formed on the second semiconductor layer, the ground transistor circuit comprising at least one ground transistor connected to at least one of the plurality of dummy word lines, wherein the at least one ground transistor is configured to be turned on based on the memory block being unselected.

11. The memory device of claim 10, wherein:
the plurality of dummy word lines comprise:
a first group of dummy word lines between the plurality of string select lines and the plurality of word lines; and
a second group of dummy word lines between the plurality of word lines and the ground select line;
the ground transistor circuit comprise:
one or more first ground transistors respectively connected to the first group of dummy word lines; and
one or more second ground transistors respectively connected to the second group of dummy word lines.

12. The memory device of claim 10, wherein a number of the at least one ground transistor of the ground transistor circuit is smaller than a number of the plurality of string select lines.

13. The memory device of claim 10, wherein a number of the at least one ground transistor of the ground transistor circuit is smaller than a number of the plurality of pass transistors of the pass transistor circuit.

14. The memory device of claim 10, wherein a first end of a ground transistor of the at least one ground transistor is configured to be applied with a ground voltage, and a second end of the ground transistor of the at least one ground transistor is connected to a dummy word line of the plurality of dummy word lines.

15. The memory device of claim 10, wherein:
based on the memory block being selected, the pass transistor circuit is configured to drive, in response to a first phase of a first block select signal, the plurality of string select lines and the plurality of word lines, and the ground transistor circuit is configured to be turned off in response to a first phase of a second block select signal; and
based on the memory block being unselected, the ground transistor circuit is configured to drive, in response to a second phase of the second block select signal, the plurality of word lines, and the pass transistor circuit is configured to be turned off in response to a second phase of the first block select signal.

16. The memory device of claim 15, wherein:
during a read operation of the memory block, based on the memory block being unselected, the plurality of word lines are configured to be applied with a ground voltage level, and the plurality of string select lines are configured to be floated.

17. The memory device of claim 15, wherein:
during a program operation of the memory block, based on the memory block being unselected, the plurality of word lines are configured to be applied with a ground voltage level, and the plurality of string select lines are configured to be floated.

18. A memory device comprising:
a memory block comprising a plurality of control lines, wherein:
the plurality of control lines comprises a plurality of string select lines, a plurality of word lines, a ground select line, and a plurality of dummy word lines arranged between the plurality of string select lines and the plurality of word lines or between the ground select line and the plurality of word lines; and
the plurality of control lines comprise a first group of control lines, and the first group of control lines comprises at least one of the plurality of word lines and at least one of the plurality of dummy word lines;
a pass transistor circuit comprising pass transistors respectively connected to the plurality of control lines; and
a ground transistor circuit comprising at least one ground transistor respectively connected to the first group of control lines.

19. The memory device of claim 18, wherein:
the first group of control lines comprises the plurality of dummy word lines and the ground select line,
the pass transistor circuit is configured to drive the plurality of control lines,
the ground transistor circuit is configured to drive the first group of control lines, and
a number of the at least one ground transistor of the ground transistor circuit is smaller than a number of the pass transistors of the pass transistor circuit.

20. The memory device of claim 18, wherein
the pass transistor circuit is configured to drive, based on the memory block being selected and in response to a first block select signal, the string select lines of the plurality of control lines, and
the string select lines of the plurality of control lines are configured to be floated based on the memory block being unselected.
